(19) United States
(12) Patent Application Publication
(10) Pub. No.: US 2017/0223872 A1
(43) Pub. Date: Aug. 3, 2017

(54) HEAT DISSIPATION DEVICE FOR WIRELESS TRANSMISSION SYSTEM

(71) Applicant: TRANS ELECTRIC CO., LTD., Changhua (TW)

(72) Inventor: Yung-Hsiang LIN, Changhua (TW)

(21) Appl. No.: 15/168,281

(22) Filed: May 31, 2016

(30) Foreign Application Priority Data
Jan. 28, 2016 (TW) 105201292

(51) Int. Cl. H05K 7/20

(52) U.S. Cl. CPC H05K 7/20418

(57) ABSTRACT

A heat dissipation device, which is used in a wireless transmission system including an operating unit and a transmission unit, includes a case unit and a heat dissipation unit. The case unit includes a first case and a second case that cooperatively define a space therebetween for receiving the wireless transmission system. The first case is formed with multiple heat dissipation holes spatially communicating the space with the environment. The heat dissipation unit includes a first dissipation member made of metal and, a second heat dissipation member made of a non-metal material, and a third heat dissipation member connected to the first heat dissipation member and being exposed to the environment.

### CROSS-REFERENCE TO RELATED APPLICATION

This application claims priority of Taiwanese Utility Model Application No. 105201292, filed on Jan. 28, 2016.

### FIELD

The disclosure relates to a heat dissipation device, and more particularly to a heat dissipation device for a wireless transmission system.

### BACKGROUND

With the growing prominence of digital lifestyle in the world, a great number of messages are transmitted and received between various types of communicating systems in our daily life. Conventional analog or digital TV, which is incapable of connecting to other communicating systems or to the Internet for viewing videos, can no longer meet people's need. Thus, a wireless video transmission device is adapted to be installed on a conventional digital TV for transforming the conventional digital TV into a smart TV.

Referring to FIG. 1, a conventional wireless video transmission device includes a case 410, a circuit board 420 disposed in the case 410, a plurality of heat dissipation members 430, and a plurality of chips 440 disposed between the circuit board 420 and the heat dissipation members 430. In order for the circuit board 420 to receive wireless signals properly, the case 410 and the heat dissipation members 430 must be made of a non-metal material so as to prevent interference of the signals, but such design is disadvantageous for heat dissipation of the circuit board 420. In addition, since the case 410 is not formed with a sufficient number of vent holes for heat dissipation, the operating efficiency of the chips 440 may be adversely affected, and the conventional wireless video transmission device may be damaged due to overheating.

### SUMMARY

Therefore, an object of the disclosure is to provide a heat dissipation device that can alleviate at least one of the drawbacks of the prior art.

According to the disclosure, the heat dissipation device is adapted to be used in a wireless transmission system that includes an operating unit and a wireless transmission unit. The heat dissipation device includes a case unit and a heat dissipation unit.

The case unit includes a first case and a second case. The first case and the second case cooperatively define a receiving space therebetween for receiving the operating unit and the wireless transmission unit. The first case is formed with a plurality of heat dissipation holes that spatially communicate the receiving space with an ambient environment.

The heat dissipation unit includes a first heat dissipation member made of a metal material, a second heat dissipation member made of a non-metal material, and at least one third heat dissipation member. The first heat dissipation member is disposed in the receiving space for contacting the operating unit to dissipate heat generated by the operating unit. The second heat dissipation member is disposed in the receiving space for contacting the wireless transmission unit to dissipate heat generated by the wireless transmission unit. The at least one third heat dissipation member is connected to the first heat dissipation member and is exposed to the ambient environment.

### BRIEF DESCRIPTION OF THE DRAWINGS

Other features and advantages of the disclosure will become apparent in the following detailed description of the embodiment with reference to the accompanying drawings, of which:

FIG. 1 is a is a partly exploded perspective view of a conventional wireless video transmission device;

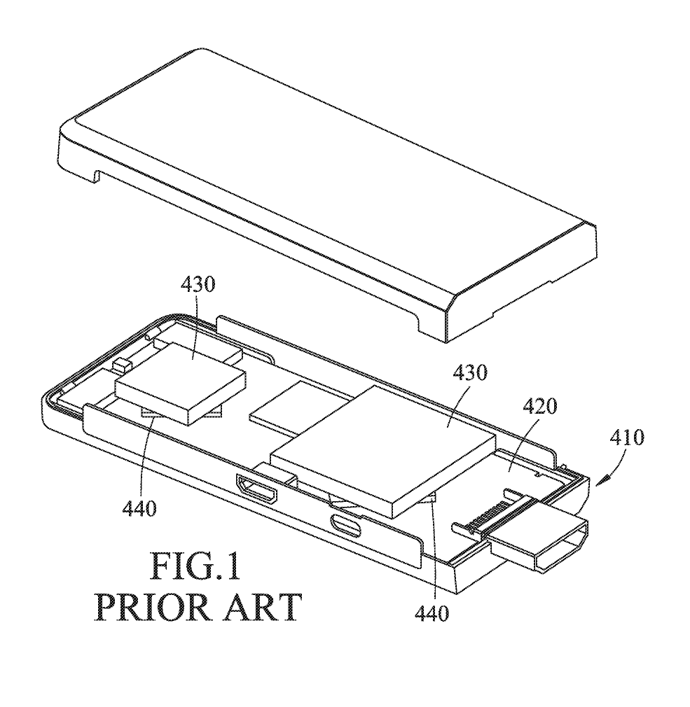

FIG. 2 is a partly exploded perspective view illustrating an embodiment of a heat dissipation device adapted to be used in a wireless transmission system according to the disclosure; and

FIG. 3 is a cross-sectional view of the embodiment.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

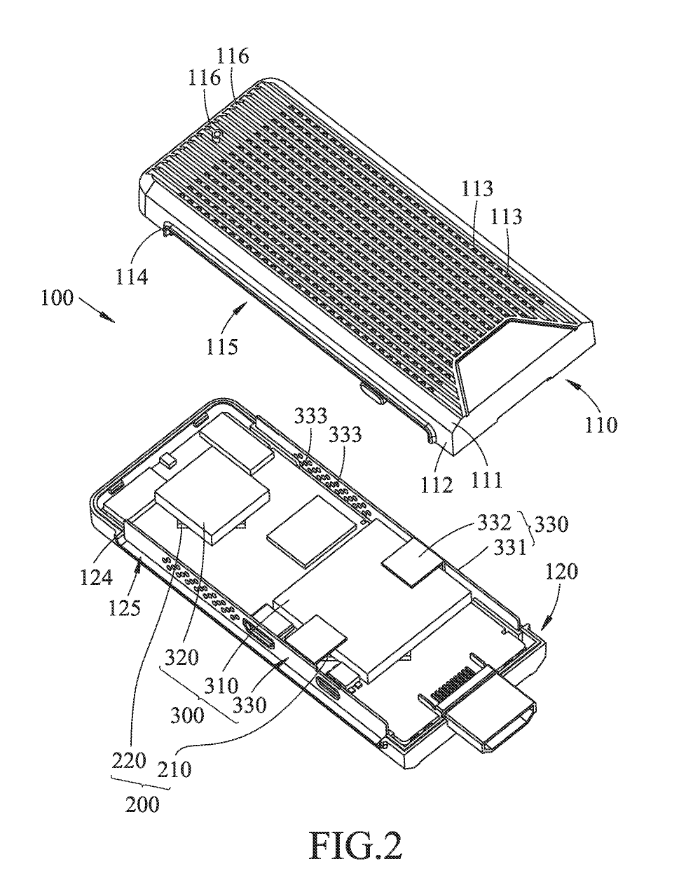

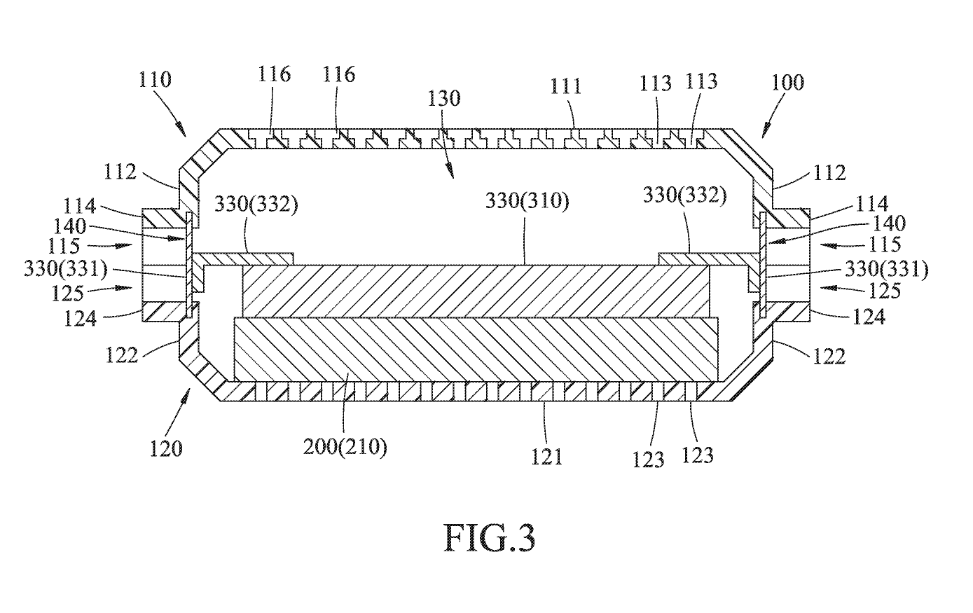

Referring to FIGS. 2 to 3, an embodiment of a heat dissipation device according to the present disclosure includes a case unit 100 and a heat dissipation unit 300, and is adapted to be used in a wireless transmission system 200 that includes an operating unit 210 and a wireless transmission unit 220.

The case unit 100 includes a first case 110 and a second case 120 that cooperatively define a receiving space 130 therebetween for receiving the operating unit 210 and the wireless transmission unit 220.

The first case 110 includes a first base wall 111, two first side walls 112 and two first flanges 114, and is formed with a plurality of heat dissipation holes 113 that extend through the first base wall 111 and that spatially communicate the receiving space 130 with an ambient environment. In this embodiment, the first base wall 111 further includes a plurality of grooves 116 arranged in parallel. The first side walls 112 respectively extend from opposite sides of the first base wall 111 toward the second case 120. Each of the first side walls 112 is formed with a first recess 115. The first flanges 114 extend outwardly and respectively from the first side walls 112.

The second case 120 includes a second base wall 121, two second side walls 122, two second flanges 124, and is formed with a plurality of heat dissipation holes 123 that extend through the second base wall 121 and that spatially communicate the receiving space 130 with the ambient environment. The second side walls 122 respectively extend from opposite sides of the second base wall 121 toward the first case 110. Each of the second side walls 122 is formed with a second recess 125 that cooperates with the first recess 115 of a respective one of the first side walls 112 to form a heat dissipation opening 140 that is in spatial communication with the receiving space 130. The second flanges 124 extend outwardly and respectively from the second side walls 122. The heat dissipation opening 140 is surrounded by a respective one of the first flanges 114 and a respective one of the second flanges 124.

It is noted that each of the heat dissipation holes 113 is arranged in a corresponding one of the grooves 116, such that heat exiting from the receiving space 130 through the heat dissipation holes 113 can be guided by the grooves 116 to increase heat dissipation efficiency of the heat dissipation device. The position and the size of the heat dissipation holes 113, 123 not only affect the heat dissipation efficiency of the heat dissipation device, but also affect the structural strength and processing complexity of the first case 110 and the second case 120 of the case unit 100. Therefore, in considering the above factors, the heat dissipation holes 113, 123 may be positioned at locations that correspond to those of the operating unit 210 and the wireless transmission unit 220 for effective heat dissipation. Moreover, in order to maintain the structural strength of the case unit 100, it is desirable to configure the heat dissipation holes 113, 123 to have smaller diameter and higher density. In this embodiment, each of the first case 110 and the second case 120 is made of plastic. The electronic circuit unit 200 may be spaced apart from the second base wall 121 of the second case 120 to facilitate the air circulation between the receiving space 130 and the ambient environment. In one embodiment, the electronic circuit unit 200 contacts the second base wall 121 of the second case 120, and the heat dissipation holes 123 may be omitted.

The operating unit 210 is used for signal processing, such as encoding, decoding, graphics acceleration, etc. The wireless transmission unit 220 is used for wireless signal transmission.

In this embodiment, each of the operating unit 210 and the wireless transmission unit 220 is a microchip which generates a large amount of heat during operation, and dissipation of the heat is thus required.

In this embodiment, the heat dissipation unit 300 includes a first heat dissipation member 310 made of a metal material, a second heat dissipation member 320 made of a non-metal material, and two third heat dissipation members 330.

The first heat dissipation member 310 is disposed in the receiving space 130, and contacts the operating unit 210 to dissipate heat generated by the operating unit 210. The second heat dissipation member 320 is disposed in the receiving space 130, and contacts the wireless transmission unit 220 to dissipate heat generated by the wireless transmission unit 220. The second heat dissipation member 320 is spaced apart from the first heat dissipation member 310. The third heat dissipation members 330 are connected to the first heat dissipation member 310 and are exposed to the ambient environment. Specifically, each of the third heat dissipation members 330 includes a first heat conductive element 331 and a second heat conductive element 332. The second heat conductive element 332 of each of the third heat dissipation members 330 is connected to the first heat dissipation member 310, and the first heat conductive element 331 of the third heat dissipation member 330 is connected to the second heat conductive element 332, is exposed to the ambient environment via a corresponding one of the heat dissipation openings 140, and covers the corresponding heat dissipation opening 140. In this embodiment, the first heat conductive element 331 of each of the heat dissipation members 330 is formed with a plurality of through holes 333 that spatially communicate the receiving space 130 with the ambient environment. In this embodiment, each of the third heat dissipation members 330 is made of metal. To be more specific, for each third heat dissipation member 330, the first heat conductive element 331 is made of aluminum, and the second heat conductive element 332 is made of copper.

It is noted that the second heat dissipation member 320 may be made of a ceramic material for efficiently dissipating heat generated by the wireless transmission unit 220, while preventing interference of the signal transmission of the wireless transmission unit 220. The heat generated by the wireless transmission unit 220 can be conducted to the second heat dissipation member 320, and subsequently converted into infrared and dissipated in the form of heat radiation.

Compare to the wireless transmission unit 220, the operating unit 210 generates more heat. A heat dissipation member made of ceramic may not be sufficient for dissipating the heat generated by the operating unit 210. Therefore, the first heat dissipation member 310 may be made of metal that has higher heat dissipation efficiency than the ceramic material. In certain embodiments, the first heat dissipation member 310 of the heat dissipation unit 300 is made by sintering a metal powder having a particle diameter that ranges from 2 nm to 100 nm. The first heat dissipation member 310 thus made has a greater total surface area and thus provides higher heat dissipation efficiency than a conventional heat dissipation member of the same dimension. Furthermore, due to the superior heat dissipation efficiency of the first heat dissipation member 310, the first heat dissipation member 310 may be made to have a smaller size compared to the conventional heat dissipation member, thereby decreasing manufacturing costs and reducing interference of the signal transmission of the wire less transmission unit 220. In certain embodiment, the first heat dissipation member 310 is made of aluminum.

With the first heat conductive element 331 of each of the third heat dissipation members 330 being exposed to the ambient environment, heat generated by the operating unit 210 can be efficiently dissipated. The through holes 333 formed on the first heat conductive element 331 of each of the third heat dissipation members 330 also facilitate heat dissipation from the receiving space 130 to the ambient environment. Besides, the first and second flanges 114, 124 are to prevent a user from directly touching the first heat conductive elements 331 for preventing burns.

In summary, the second heat dissipation member 320 made of a non-metal material is capable of efficiently dissipating heat generated by the wireless transmission unit 220, while avoiding interference of the signal transmission of the wireless transmission unit 220. The first heat dissipation member 310 made of metal is capable of efficiently dissipating heat generated by the operating unit 210, and the third heat dissipation members 330 facilitate heat dissipation of the operating unit 210. The heat dissipation holes 113, 123 and the through holes 333 facilitate heat dissipation from the receiving space 130 to the ambient environment.

In the description above, for the purposes of explanation, numerous specific details have been set forth in order to provide a thorough understanding of the embodiment. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects.

While the disclosure has been described in connection with what is considered the exemplary embodiment, it is understood that this disclosure is not limited to the disclosed embodiment but is intended to cover various arrangements included within the spirit and scope of the broadest interpretation so as to encompass all such modifications and equivalent arrangements.

What is claimed is:

1. A heat dissipation device adapted to be used in a wireless transmission system that includes an operating unit and a wireless transmission unit, said heat dissipation device comprising:
a case unit that includes a first case and a second case, said first case and said second case cooperatively defining a receiving space therebetween for receiving the operating unit and the wireless transmission unit, said first case being formed with a plurality of heat dissipation holes that spatially communicate said receiving space with an ambient environment; and
a heat dissipation unit that includes a first heat dissipation member made of a metal material, a second heat dissipation member made of a non-metal material, and at least one third heat dissipation member, said first heat dissipation member being disposed in said receiving space for contacting the operating unit to dissipate heat generated by the operating unit, said second heat dissipation member being disposed in said receiving space for contacting the wireless transmission unit to dissipate heat generated by the wireless transmission unit, said at least one third heat dissipation member being connected to said first heat dissipation member and being exposed to the ambient environment.

2. The heat dissipation device as claimed in claim 1, wherein said at least one third heat dissipation member includes a first heat conductive element and a second heat conductive element, said second heat conductive element being connected to said first heat dissipation member, said first heat conductive element being connected to said second heat conductive element and being exposed to the ambient environment.

3. The heat dissipation device as claimed in claim 2, wherein said first heat conductive element of said at least one heat dissipation member is formed with a plurality of through holes that spatially communicate said receiving space with the ambient environment.

4. The heat dissipation device as claimed in claim 2, wherein said heat dissipation unit includes two of said third heat dissipation members.

5. The heat dissipation device as claimed in claim 4, wherein said first case includes a first base wall and two first side walls, said heat dissipation holes extending through said first base wall, said first side walls respectively extending from opposite sides of said first base wall toward said second case, each of said first side walls being formed with a first recess, said second case including a second base wall and two second side walls, said second side walls respectively extending from opposite sides of said second base wall toward said first case, each of said second side walls being formed with a second recess that cooperates with said first recess of a respective one of said first side walls to form a heat dissipation opening, said heat dissipation opening being in spatial communication with said receiving space and covered by said first heat conductive element of a respective one of said third heat dissipation members.

6. The heat dissipation device as claimed in claim 5, wherein said first case further includes two first flanges that extend outwardly and respectively from said first side walls, said second case further including two second flanges that extend outwardly and respectively from said second side walls, said heat dissipation opening being surrounded by a respective one of said first flanges and a respective one of said second flanges.

7. The heat dissipation device as claimed in claim 1, wherein said first heat dissipation member of said heat dissipation unit is made by sintering a metal powder having a particle diameter that ranges from 2 nm to 100 nm.

8. The heat dissipation device as claimed in claim 1, wherein said first heat dissipation member of said heat dissipation unit is made of aluminum.

9. The heat dissipation device as claimed in claim 1, wherein said second heat dissipation member of said heat dissipation unit is made of a ceramic material.

10. The heat dissipation device as claimed in claim 1, wherein said at least one third heat dissipation member is made of metal.

11. The heat dissipation device as claimed in claim 2, wherein said first heat conductive element of said at least one third heat dissipation member is made of aluminum.

12. The heat dissipation device as claimed in claim 2, wherein said second heat conductive element of said at least one third heat dissipation member is made of copper.

13. The heat dissipation device as claimed in claim 1, wherein each of said first case and said second case is made of plastic.
